(19) United States
(12) Patent Application Publication
(10) Pub. No.: US 2024/0162344 A1
(43) Pub. Date: May 16, 2024

(54) SEMICONDUCTOR DEVICE

(71) Applicant: ROHM CO., LTD., Kyoto (JP)

(72) Inventor: Shu NAKASHIMA, Kyoto (JP)

(73) Assignee: ROHM CO., LTD., Kyoto (JP)

(21) Appl. No.: 18/507,146

(22) Filed: Nov. 13, 2023

(30) Foreign Application Priority Data
Nov. 14, 2022 (JP) 2022-181717

(51) Int. Cl. H01L 29/78; H01L 27/02; H01L 29/06; H01L 29/10; H01L 29/739; H01L 29/861

(52) U.S. Cl. CPC H01L 29/7803; H01L 27/0255; H01L 29/0696; H01L 29/1095; H01L 29/7395; H01L 29/861

(57) ABSTRACT

A semiconductor device includes: a first semiconductor layer of a first conductivity type; at least one second semiconductor layer of a second conductivity type formed in the first semiconductor layer to have an annular shape in plan view; an insulating layer formed on the first semiconductor layer; a first metal layer and a second metal layer formed on the insulating layer and spaced apart from each other; a second wiring layer provided in the insulating layer and configured to electrically connect an inner region of the first semiconductor layer surrounded by the at least one second semiconductor layer and the second metal layer; and a first wiring layer provided in the insulating layer and configured to electrically connect an outer region of the first semiconductor layer on the opposite side from the inner region with respect to the at least one second semiconductor layer and the first metal layer.

### CROSS-REFERENCE TO RELATED APPLICATION

This application is based upon and claims the benefit of priority from Japanese Patent Application No. 2022-181717, filed on Nov. 14, 2022, the entire contents of which are incorporated herein by reference.

### TECHNICAL FIELD

The present disclosure relates to a semiconductor device.

### BACKGROUND

In the related art, semiconductor devices are used as switching elements for power conversion and the like. For example, a MOSFET or an IGBT disclosed in the related art is used as a semiconductor device for a vehicle-mounted inverter device.

### BRIEF DESCRIPTION OF DRAWINGS

The accompanying drawings, which are incorporated in and constitute a part of the specification, illustrate embodiments of the present disclosure.

FIG. 1 is a schematic plan view showing a semiconductor device according to an embodiment of the present disclosure.

FIG. 2 is a schematic plan view showing a metal layer and a semiconductor layer in the semiconductor device shown in FIG. 1.

FIG. 3 is an enlarged schematic plan view showing a portion of the semiconductor device shown in FIG. 1.

FIG. 4 is a schematic plan view for explaining the semiconductor layer without the metal layer shown in FIG. 3.

FIG. 5 is a cross-sectional view taken along line F5-F5 in FIG. 3.

FIG. 6 is a cross-sectional view taken along line F6-F6 in FIG. 3.

FIG. 7 is a schematic plan view showing a semiconductor device according to a modification.

FIG. 8 is an enlarged schematic plan view showing a portion of the semiconductor device shown in FIG. 7.

FIG. 9 is a schematic cross-sectional view showing a cell of a modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, several embodiments of a semiconductor device of the present disclosure will be described with reference to the accompanying drawings. For simplicity and clarity of explanation, components shown in the drawings are not necessarily drawn on a constant scale. Further, to facilitate understanding, hatching lines may be omitted in cross-sectional views. The accompanying drawings merely illustrate embodiments of the present disclosure and should not be considered as limiting the present disclosure. The terms such as “first,” “second,” and “third” in the present disclosure are used merely to distinguish among objects, and are not intended to rank the objects.

The following detailed description includes apparatuses, systems, and methods that embody exemplary embodiments of the present disclosure. This detailed description is only illustrative in nature and is not intended to limit the embodiments of the present disclosure or application and use of such embodiments.

### (Plan-View Layout of Semiconductor Device)

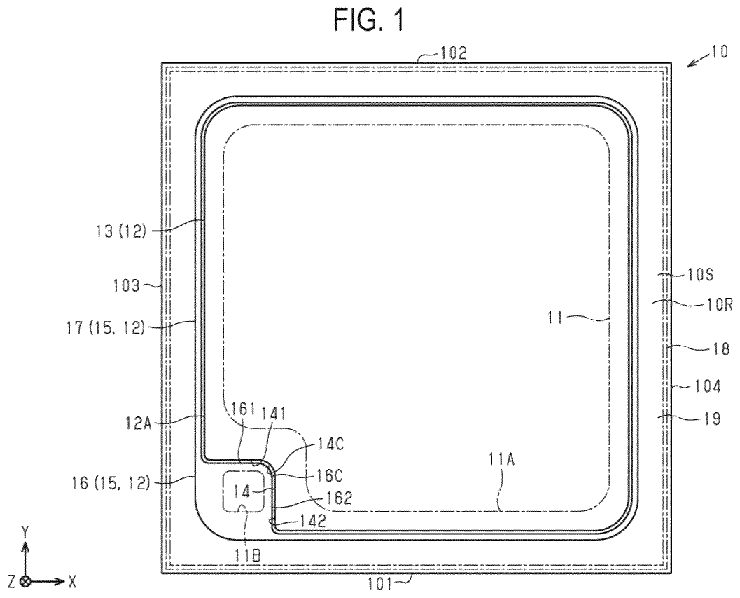

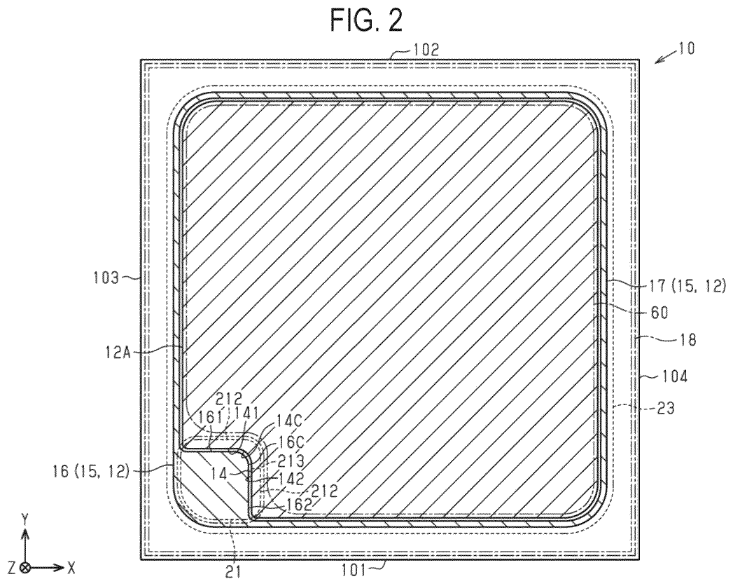

FIGS. 1 and 2 are schematic plan views of a semiconductor device 10 according to an embodiment of the present disclosure. In FIG. 2, some elements of the semiconductor device 10 shown in FIG. 1 are transparent. More specifically, FIG. 2 is a schematic plan view of the semiconductor device 10 without a passivation layer 11 of FIG. 1. Further, in FIG. 1, the passivation layer 11 is indicated by a one-dot chain line, and the metal layer 12 is indicated by a solid line.

The term “plan view” used in the present disclosure refers to viewing the semiconductor device 10 in a Z direction of mutually orthogonal X, Y, and Z axes shown in FIG. 1. Unless explicitly stated otherwise, the term “plan view” refers to viewing the semiconductor device 10 from above along the Z-axis.

As shown in FIG. 1, the semiconductor device 10 may have a rectangular shape in a plan view. The semiconductor device 10 is a semiconductor switching device including, for example, a MOSFET (Metal Oxide Semiconductor Field Effect Transistor). For example, the semiconductor device 10 is a semiconductor switching device including an SJ-MOSFET (Super Junction-MOSFET).

In an example, the semiconductor device 10 may have a square shape in the plan view. The semiconductor device 10 includes an upper surface 10S, a lower surface 10R, and a plurality of side surfaces 101, 102, 103, and 104. The upper surface 10S and the lower surface 10R face opposite sides in the Z direction. Each of the side surfaces 101 to 104 connects the upper surface 10S and the lower surface 10R. The first side surface 101 and the second side surface 102 extend along an X direction. The third side surface 103 and the fourth side surface 104 extend along a Y direction.

The semiconductor device 10 may include a passivation layer 11. The passivation layer 11 may be made of any material capable of protecting an underlying structure. In an example, the passivation layer 11 may be made of silicon nitride (SiN). The passivation layer 11 may include pad openings 11A and 11B.

The semiconductor device 10 may further include a metal layer 12. The passivation layer 11 at least partially covers the metal layer 12. The metal layer 12 may be made of at least one selected from the group of titanium (Ti), nickel (Ni), gold (Au), silver (Ag), copper (Cu), aluminum (Al), a Cu alloy, and an Al alloy. In an example, the metal layer 12 may be made of an AlCu alloy.

The metal layer 12 may include a first metal layer 13 and a second metal layer 15. The first metal layer 13 and the second metal layer 15 are spaced apart from each other. In an example, the second metal layer 15 may be formed to surround the first metal layer 13.

In an example, the first metal layer 13 may include a source electrode. Hereinafter, the first metal layer 13 will be described as a source electrode 13. A portion of the source electrode 13 is exposed through the first pad opening 11A of the passivation layer 11. The portion of the source electrode 13 exposed through the first pad opening 11A functions as an external terminal (source pad) to which a conductor (e.g., a bonding wire) is connected.

The source electrode 13 may include a recess 14 by having a substantially rectangular cutout in a plan view. The recess 14 may be formed at an end of the source electrode 13 close to two adjacent side surfaces among the four side surfaces 101, 102, 103, and 104 of the semiconductor device 10. In the example of FIGS. 1 and 2, the recess 14 may be formed in a region close to a point where the first side surface 101 and the third side surface 103 of the semiconductor device 10 intersect.

The source electrode 13 includes a first side 141 and a second side 142 that form the recess 14, and a curved portion 14C between the first side 141 and the second side 142. The first side 141 extends along the X-axis and the Y-axis in the plan view. The second side 142 extends along the Y-axis in the plan view. The curved portion 14C is formed in an arc shape recessed toward the center of the source electrode 13 in the plan view.

In an example, the second metal layer 15 may include a gate electrode 16 and a gate finger 17. The gate electrode 16 is arranged in the recess 14 of the source electrode 13. The gate electrode 16 is formed into a rectangular shape in a plan view. The gate electrode 16 includes a first side 161 and a second side 162 respectively adjacent to the first side 141 and the second side 142 that form the recess 14 of the source electrode 13, and a corner portion 16C between the first side 161 and the second side 162. The corner portion 16C is formed in an arc shape that bulges toward the source electrode 13. The gate finger 17 may be formed integrally with the gate electrode 16. The gate finger 17 is formed to surround the source electrode 13.

A portion of the gate electrode 16 is exposed through the second pad opening 11B of the passivation layer 11. The portion of the gate electrode 16 exposed through the second pad opening 11B functions as an external terminal (gate pad) to which a conductor (e.g., a bonding wire) is connected.

The semiconductor device 10 may include an outer peripheral electrode 18. The outer peripheral electrode 18 may be included in the metal layer 12. The outer peripheral electrode 18 and the source electrode 13 are spaced apart from each other. The outer peripheral electrode 18 is formed to surround the source electrode 13. The outer peripheral electrode 18 is formed in an annular shape extending along the side surfaces 101 to 104 of the semiconductor device 10 in a plan view.

As shown in FIG. 2, the semiconductor device 10 may include a cell region 60 that contributes to an operation of the semiconductor device 10 as a transistor. The cell region 60 may overlap with the source electrode 13 in a plan view. The cell region 60 may have a similar shape to the source electrode 13 including the recess 14 in a plan view. The cell region 60 may be smaller than the source electrode 13 including the recess 14 in the plan view.

As shown in FIG. 2, the semiconductor device 10 includes a first semiconductor layer 21. The first semiconductor layer 21 is formed so as to overlap with a portion of the source electrode 13 and a portion of the gate electrode 16 in the plan view. In an example, the first semiconductor layer 21 may be made of conductive polysilicon. Further, the first semiconductor layer 21 may be configured as a first conductivity type containing a predetermined impurity. The first semiconductor layer 21 contains, for example, a first conductivity type impurity as the impurity. The first conductivity type is, for example, an n-type. For example, the first semiconductor layer 21 may be made of n-type polysilicon.

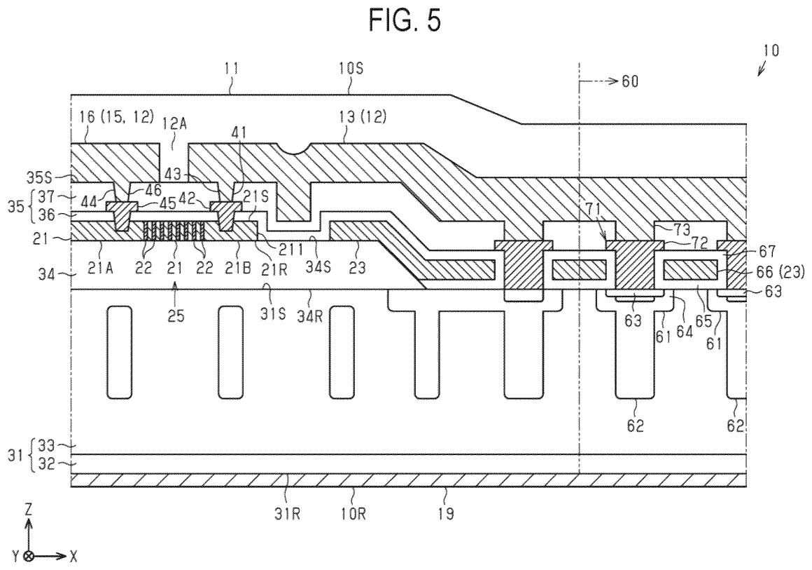

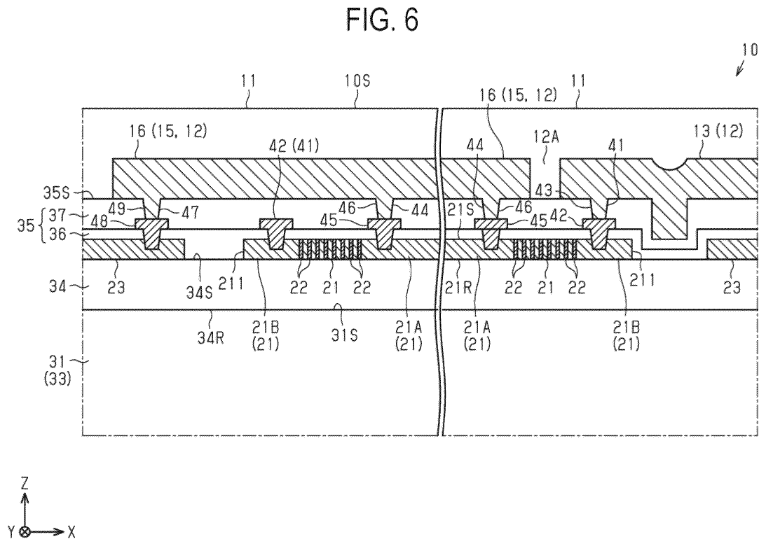

Further, the semiconductor device 10 includes a third semiconductor layer 23 formed to surround the first semiconductor layer 21. In an example, the third semiconductor layer 23 is formed to overlap with the cell region 60 and the gate finger 17 in the plan view. A portion of the third semiconductor layer 23 overlapping with the cell region 60 forms a control electrode (gate electrode) 66 (see FIG. 5) of a transistor included in the cell region 60. A portion of the third semiconductor layer 23 overlapping with the gate finger 17 is electrically connected to the gate finger 17 by a third wiring layer 47 (see FIG. 6). In FIG. 2, the entire third semiconductor layer 23 is hatched. However, in the cell region 60, the third semiconductor layer 23 is formed only in the portion that will become the control electrode (gate electrode) 66 of the transistor.

### (Configurations of First Semiconductor Layer, Second Semiconductor Layer, Protection Diode and Wiring Layer)

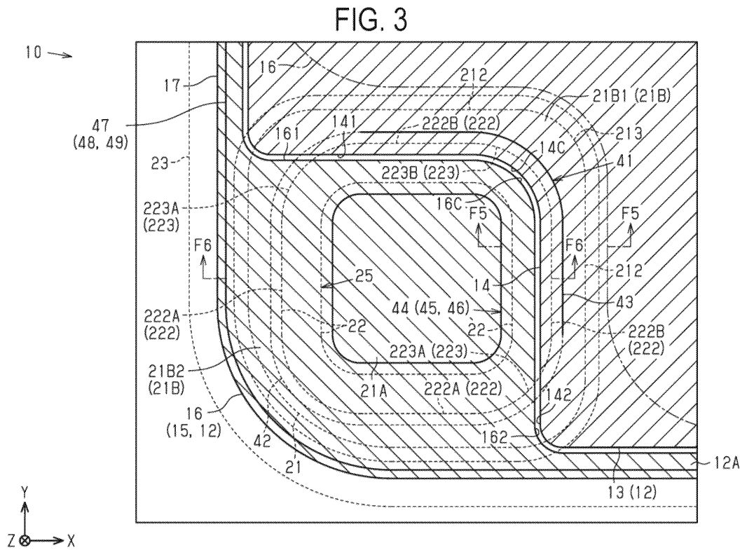

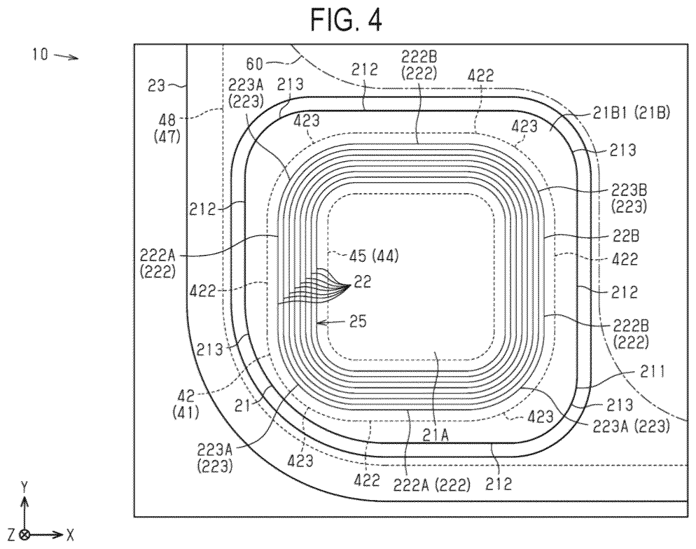

FIG. 3 is an enlarged schematic plan view showing a portion of the semiconductor device 10, in which view a relationship between the gate electrode 16 and the source electrode 13 and the first semiconductor layer 21 is shown. FIG. 4 is a schematic plan view for explaining the first semiconductor layer 21 and the second semiconductor layer 22 without the first metal layer 13 and the second metal layer 15 shown in FIG. 3. FIG. 5 is a cross-sectional view taken along line F5-F5 in FIG. 3. FIG. 6 is a cross-sectional view taken along line F6-F6 in FIG. 3.

As shown in FIGS. 5 and 6, the semiconductor device 10 may include a semiconductor layer 31. The source electrode 13 (first metal layer 13) and gate electrode 16 (second metal layer 15) are formed on the semiconductor layer 31. The semiconductor layer 31 includes an upper surface 31S and a lower surface 31R opposite the upper surface 31S (see FIG. 5). The Z direction shown in FIG. 2 corresponds to a direction orthogonal to the upper surface 31S and lower surface 31R of the semiconductor layer 31. The semiconductor layer 31 may be made of at least one selected from the group of silicon (Si), silicon carbide (SiC), gallium nitride (GaN), and gallium oxide (Ga₂O₃). The semiconductor layer 31 may be made of Si, for example.

The semiconductor layer 31 may include a semiconductor substrate 32 including the lower surface 31R of the semiconductor layer 31, and an epitaxial layer 33 formed on the semiconductor substrate 32 and including the upper surface 31S of the semiconductor layer 31. In an example, the semiconductor substrate 32 may be a Si substrate. The semiconductor substrate 32 may correspond to a drain region of a MOSFET. The drain region (semiconductor substrate 32) may be a p⁺-type region containing a p-type impurity. The epitaxial layer 33 may be a Si layer formed on the semiconductor substrate 32. In an example, the epitaxial layer 33 may be an epitaxially-grown Si layer. The epitaxial layer 33 is an n-type drift layer.

The semiconductor device 10 includes a third metal layer 19 formed on the lower surface 31R of the semiconductor layer 31. In an example, the third metal layer 19 is a drain electrode. The third metal layer 19 may be formed of at least one selected from the group of Ti, Ni, Au, Ag, Cu, Al, a Cu alloy, and an Al alloy.

The semiconductor device 10 may further include an insulating layer 34 formed on the upper surface 31S of the semiconductor layer 31. The insulating layer 34 is in contact with the upper surface 31S of the semiconductor layer 31. The insulating layer 34 includes an upper surface 34S and a lower surface 34R. The lower surface 34R of the insulating layer 34 is in contact with the upper surface 31S of the semiconductor layer 31. The insulating layer 34 may be formed from a silicon oxide film (SiO₂), for example. The insulating layer 34 is, for example, a field oxide film. Additionally or alternatively, the insulating layer 34 may include a film made of an insulating material other than SiO₂, for example, SiN.

As shown in FIGS. 3 and 4, the first semiconductor layer 21 is formed into a rectangular shape in a plan view. The first semiconductor layer 21 includes a side surface 211 that connects an upper surface 21S and a lower surface 21R (see FIGS. 5 and 6). The side surface 211 includes four straight portions 212 and corner portions 213 between two circumferentially adjacent straight portions 212. In an example, the straight portions 212 extend along the X direction or the Y direction. The corner portions 213 are formed in an arc shape that bulges toward the outside of the first semiconductor layer 21.

As shown in FIGS. 5 and 6, the second semiconductor layer 22 is provided within the first semiconductor layer 21. In an example, the second semiconductor layer 22 may be made of conductive polysilicon. Further, the second semiconductor layer 22 may be configured as a first conductivity type containing a predetermined impurity. As for the impurity, for example, the second semiconductor layer 22 contains an impurity of a second conductivity type different from the first conductivity type. The second conductivity type is, for example, a p-type. For example, the second semiconductor layer 22 may be made of p-type polysilicon.

The second semiconductor layer 22 is formed to penetrate the first semiconductor layer 21 from the upper surface 21S of the first semiconductor layer 21 to the lower surface 21R of the first semiconductor layer 21. A plurality of second semiconductor layers 22 is provided. The number of second semiconductor layers 22 is eight in an example. The number of second semiconductor layers 22 may be changed as appropriate. The number of second semiconductor layers 22 may be any number equal to or greater than three.

As shown in FIGS. 3 and 4, the second semiconductor layers 22 are formed in an annular shape. FIG. 4 shows a region where the second semiconductor layers 22 are formed by a second semiconductor layer 22 at the outermost periphery and a second semiconductor layer 22 at the innermost periphery. The second semiconductor layers 22 are spaced apart from each other within the first semiconductor layer 21. Therefore, the semiconductor device 10 includes a plurality of diodes 25 formed by arranging a plurality of p-type second semiconductor layers 22 at intervals in an n-type first semiconductor layer 21.

Each of the second semiconductor layers 22 includes four straight portions 222 and four corner portions 223 respectively provided between two circumferentially adjacent straight portions 222. Each of the corner portions 223 is formed in an arc shape that bulges toward the outer region 21B of the first semiconductor layer 21.

The first semiconductor layer 21 includes an inner region 21A surrounded by the annular second semiconductor layer 22, and an outer region 21B on the opposite side from the inner region 21A with respect to the annular second semiconductor layer 22. The first semiconductor layer 21 is arranged so that the entire inner region 21A overlaps with the gate electrode 16.

Further, the first semiconductor layer 21 is arranged such that a gap 12A between the gate electrode 16 and the source electrode 13 is located between the inner region 21A and the outer region 21B. More specifically, the gap 12A between the gate electrode 16 and the source electrode 13 is arranged to overlap with a region in which the first semiconductor layers 21 and the second semiconductor layers 22 are alternately arranged and which constitute a plurality of diodes 25. Therefore, the outer region 21B includes a first overlapping region 21B1 overlapping with the source electrode 13 and a second overlapping region 21B2 overlapping with the gate electrode 16 in the plan view.

As shown in FIGS. 5 and 6, the semiconductor device 10 includes an insulating layer 35 formed on the first semiconductor layer 21. The insulating layer 35 is formed to cover the first semiconductor layer 21 and the second semiconductor layer 22. The insulating layer 35 is in contact with the upper surface 21S of the first semiconductor layer 21 and the upper surface of the second semiconductor layer 22.

The insulating layer 35 includes a first insulating layer 36 formed on the first semiconductor layer 21 and a second insulating layer 37 formed on the first insulating layer 36. In an example, the first insulating layer 36 and the second insulating layer 37 may be made of SiO₂. The first insulating layer 36 and the second insulating layer 37 may be made of an insulating material different from SiO₂, for example, SiN. Furthermore, the first insulating layer 36 and the second insulating layer 37 may be made of different materials. The source electrode 13 and the gate electrode 16 described above are formed on the insulating layer 35, more specifically, on the second insulating layer 37. The source electrode 13 and the gate electrode 16 are in contact with the upper surface 35S of the insulating layer 35 (the upper surface of the second insulating layer 37).

As shown in FIGS. 5 and 6, the semiconductor device 10 further includes a first wiring layer 41 provided within the insulating layer 35 and configured to electrically connect the outer region 21B of the first semiconductor layer 21 and the source electrode 13. The first wiring layer 41 includes a first main body portion 42 and a first connection portion 43. The first main body portion 42 is embedded within the insulating layer 35 at a position overlapping with the outer region 21B. In an example, the first main body portion 42 is provided within the first insulating layer 36. The first main body portion 42 is formed to penetrate the first insulating layer 36 and is electrically connected to the outer region 21B. The first main body portion 42 may be made of at least one selected from the group of Cu, tungsten (W), Ti, and titanium nitride (TiN).

As shown in FIG. 4, the first main body portion 42 is formed in an annular shape so as to surround the second semiconductor layer 22. The first main body portion 42 includes, in the outer region 21B, a portion overlapping with the first overlapping region 21B1 and a portion overlapping with the second overlapping region 21B2. The first main body portion 42 is electrically connected to the outer region 21B. The first main body portion 42 is formed along the straight portions 222 and the corner portions 223 of the second semiconductor layer 22. Therefore, the first main body portion 42 includes straight portions 422 formed along the straight portions 222 of the second semiconductor layer 22 and corner portions 423 formed in an arc shape in conformity with the corner portions 223 of the second semiconductor layer 22.

As shown in FIGS. 3, 5 and 6, the first connection portion 43 is selectively provided in the insulating layer 35 at a position overlapping with the first overlapping region 21B1. As shown in FIGS. 5 and 6, the first connection portion 43 electrically connects the first main body portion 42 and the source electrode 13. The first connection portion 43 is provided within the second insulating layer 37. In an example, the first connection portion 43 is made of the same material as the source electrode 13. The first connection portion 43 may be made of W, Ti, TiN, or the like.

As shown in FIGS. 3 and 4, the first connection portion 43 is formed along two sides 161 and 162 of the gate electrode 16 adjacent to the source electrode 13 in the plan view. Further, the first connection portion 43 is formed along the corner portion 16C between the two sides 161 and 162 of the gate electrode 16. The source electrode 13 includes a first side 141 and a second side 142 that form the recess 14, and a curved portion 14C between the first side 141 and the second side 142. It may be said that the first connection portion 43 is formed along the first side 141, the second side 142, and the curved portion 14C.

As shown in FIG. 3, the outer region 21B of the first semiconductor layer 21 includes a first overlapping region 21B1 overlapping with the source electrode 13. Among the plurality of second semiconductor layers 22, at least the outermost second semiconductor layer 22B includes two straight portions 222B overlapping with the first overlapping region 21B1 and a corner portion 223B between the two straight portions 222B. The straight portions 222A and a corner portion 223A, excluding the two straight portions 222B and the corner portion 223B, do not at least partially overlap with the first overlapping region 21B1. The first connection portions 43 are provided along the two straight portions 222B and the corner portion 223B of the second semiconductor layer 22 that overlap with the first overlapping region 21B1 in the plan view. Therefore, it may be said that the first connection portion 43 is not formed in the portion corresponding to the gap 12A between the source electrode 13 and the gate electrode 16. Furthermore, it may be said that the end of the first connection portion 43 is arranged on the inner side of the first overlapping region 21B1 than the end of the first overlapping region 21B1.

The semiconductor device 10 further includes a second wiring layer 44 provided within the insulating layer 35 and configured to electrically connect the inner region 21A of the first semiconductor layer 21 and the gate electrode 16. The second wiring layer 44 includes a second main body portion 45 and a second connection portion 46. The second main body portion 45 is embedded in the insulating layer 35 at a position overlapping with the inner region 21A. As shown in FIG. 4, the second main body portion 45 is surrounded by the second semiconductor layer 22 in the plan view. The second main body portion 45 is formed in an annular shape. The second main body portion 45 is electrically connected to the inner region 21A. In an example, as shown in FIGS. 5 and 6, the second main body portion 45 is provided within the first insulating layer 36. The second main body portion 45 is formed to penetrate the first insulating layer 36 and is electrically connected to the inner region 21A. The second main body portion 45 may be made of at least one selected from the group of Cu, W, Ti, and TiN.

As shown in FIGS. 3, 5 and 6, the second connection portion 46 is provided so as to overlap with the second main body portion 45. As shown in FIGS. 5 and 6, the second connection portion 46 electrically connects the second main body portion 45 and the source electrode 13. The second connection portion 46 is provided within the second insulating layer 37. As shown in FIGS. 3 and 4, the second connection portion 46 is surrounded by the second semiconductor layer 22 in the plan view. The second connection portion 46 is formed in an annular shape. In an example, the second connection portion 46 is formed of the same material as the source electrode 13. The second connection portion 46 may be made of W, Ti, TiN, or the like.

As shown in FIG. 6, the third semiconductor layer 23 is arranged on the insulating layer 34 with a gap between the third semiconductor layer 23 and the first semiconductor layer 21. As shown in FIGS. 2 to 4, the third semiconductor layer 23 is formed to surround the first semiconductor layer 21 in a plan view. The third semiconductor layer 23 is covered with the insulating layer 35 (the first insulating layer 36 and the second insulating layer 37). A gate electrode 16 is formed on the upper surface 35S of the insulating layer 35 (the upper surface of the second insulating layer 37). The gate electrode 16 is electrically connected to the third semiconductor layer 23 via a third wiring layer 47.

The third wiring layer 47 includes a third main body portion 48 and a third connection portion 49. The third main body portion 48 is provided in the first insulating layer 36 and is formed to penetrate the first insulating layer 36. The third main body portion 48 is electrically connected to the third semiconductor layer 23. The third connection portion 49 is provided at a position overlapping with the third main body portion 48. The third connection portion 49 is formed in the second insulating layer 37. The third connection portion 49 electrically connects the third main body portion 48 and the gate electrode 16.

As shown in FIGS. 3 and 4, the gate electrode 16 includes a gate electrode 16 and a gate finger 17. The third wiring layer 47 (the third main body portion 48 and the third connection portion) is provided along the peripheral edge portion of the gate electrode 16 and along the gate finger 17. As shown in FIGS. 1 and 2, the gate finger 17 is formed to surround the source electrode 13. Although not shown in FIGS. 1 and 2, the third wiring layer 47 is provided at a position overlapping with the gate finger 17. The third wiring layer 47 formed in this manner electrically connects the gate electrode 16 and the gate finger 17 to the peripheral edge portion of the third semiconductor layer 23.

### (Cell Configuration)

As shown in FIG. 5, in the cell region 60, a channel diffusion layer 61 and a column layer 62 extending from the channel diffusion layer 61 toward the lower surface 31R of the semiconductor layer 31 are formed in the semiconductor layer 31. In an example, the channel diffusion layer 61 is of the second conductivity type (p type), and the column layer 62 is of the second conductivity type (p type). A plurality of channel diffusion layers 61 and a plurality of column layers 62 are provided at predetermined intervals along a direction parallel to the upper surface 31S of the semiconductor layer 31. A source diffusion layer 63 is formed within the channel diffusion layer 61. In an example, the source diffusion layer 63 is of the first conductivity type (n+ type).

A gate electrode 66 is formed on the epitaxial layer 33 between the adjacent channel diffusion layers 61 and on the channel region 64 of the channel diffusion layer 61 between the source diffusion layer 63 and the epitaxial layer 33 via a gate insulating film 65. The gate electrode 66 is formed of the third semiconductor layer 23. The gate electrode 66 is embedded in an interlayer insulating film 67 provided on the semiconductor layer 31. The interlayer insulating film 67 includes a gate insulating film 65 below the gate electrode 16. The interlayer insulating film 67 is constituted by the first insulating layer 36 described above.

The second insulating layer 37 described above is formed on the interlayer insulating film 67. A source electrode 13 is provided on the second insulating layer 37. The source electrode 13 is electrically connected to the source diffusion layer 63 via a source wiring layer 71. The source wiring layer 71 is an example of a first via. The source wiring layer 71 includes a source main body portion 72 and a source connection portion 73. The source main body portion 72 is provided in the first insulating layer 36 and is electrically connected to the source diffusion layer 63. The source connection portion 73 is provided at a position overlapping with the source main body portion 72 in a plan view. The source connection portion 73 is provided in the second insulating layer 37. The source connection portion 73 electrically connects the source main body portion 72 and the source electrode 13. The source wiring layer 71 is made of the same material as the first wiring layer 41 and the second wiring layer 44.

### (Operation)

Next, an operation of the semiconductor device 10 will be described. The semiconductor device 10 of the present embodiment includes the first semiconductor layer 21, the second semiconductor layer 22, the insulating layer 35, the source electrode 13, the gate electrode 16, the first wiring layer 41, and the second wiring layer 44. The second semiconductor layer 22 is formed in the first semiconductor layer 21 to have an annular shape in a plan view. The insulating layer 35 is formed on the first semiconductor layer 21. The source electrode 13 and the gate electrode 16 are formed on the insulating layer 35 and are spaced apart from each other. The second wiring layer 44 is provided in the insulating layer 35 and configured to electrically connect the inner region 21A of the first semiconductor layer 21 surrounded by the second semiconductor layer 22 and the gate electrode 16. The first wiring layer 41 is provided in the insulating layer 35 and configured to electrically connect the outer region 21B of the first semiconductor layer 21 on the opposite side from the inner region 21A with respect to the second semiconductor layer 22 and the source electrode 13. The gate electrode 16 overlaps with the entire inner region 21A in the plan view. The second wiring layer 44 is provided in the insulating layer 35 at a position overlapping with the inner region 21A to have an annular shape in the plan view.

The outer region 21B includes the first overlapping region 21B1 that overlaps with the source electrode 13 in the plan view, and the second overlapping region 21B2 that overlaps with the gate electrode 16 in the plan view. The first wiring layer 41 includes the first main body portion 42 and the first connection portion 43. The first main body portion 42 is embedded in the insulating layer 35 at a position overlapping with the outer region 21B, is formed in an annular shape to surround the second semiconductor layer 22, and is electrically connected to the outer region 21B. The first connection portion 43 is selectively provided in the insulating layer 35 at a position overlapping with the first overlapping region 21B1, and is configured to electrically connect the first main body portion 42 and the source electrode 13. In the plan view, the annular diode 25 formed by the first semiconductor layer 21 and the second semiconductor layer 22 is surrounded by the annularly formed first main body portion 42 and the second wiring layer 44. The annular diode 25 is electrically connected between the gate electrode 16 and the source electrode 13. The diode 25 functions as a protection diode (protection element) against electrostatic discharge or surge voltage caused by an externally connected inductor.

### Comparative Example

Now, a semiconductor device of a comparative example with respect to the semiconductor device 10 of the above-described embodiment will be described. Components similar to those of the semiconductor device 10 of the above-described embodiment will be described by using the same member names and reference numerals.

In the semiconductor device of the comparative example, the first semiconductor layer 21 is covered with one insulating layer, and the source electrode 13 and the gate electrode 16 are formed on the one insulating layer. In this case, the first wiring layer that electrically connects the source electrode 13 and the first semiconductor layer 21 is constituted by only the first connection portion 43. Similarly, the second wiring layer that electrically connects the gate electrode 16 and the first semiconductor layer 21 is constituted by only the second connection portion 46. In the semiconductor device of the comparative example, the portions of the second semiconductor layer 22 and the first semiconductor layer 21 interposed between the first connection portion 43 and the second connection portion 46 function as a protection diode connected between the source electrode 13 and the gate electrode 16. That is, in the semiconductor device 10 of this comparative example, only a portion of the annular second semiconductor layer 22 functions as a protection diode.

The semiconductor device 10 of the present embodiment includes the first main body portion 42 electrically connected to the source electrode 13 via the first connection portion 43. The first main body portion 42 is formed in an annular shape to surround the second semiconductor layer 22 and is electrically connected to the first semiconductor layer 21. Therefore, in the semiconductor device 10 of the present embodiment, the entire circumference of the annularly formed second semiconductor layer 22 contributes to the operation of the diode 25. In the semiconductor device 10 of the present embodiment, a length of the annular second semiconductor layer 22 may be made equal to a length of the diode 25 (diode length). A length of the annular first main body portion 42 electrically connected to the outer region 21B of the first semiconductor layer 21 may be set as a contact length. Therefore, in the semiconductor device 10 of the present embodiment, the diode length and the contact length may be increased. As a result, the semiconductor device 10 of the present embodiment may improve ESD resistance.

The second wiring layer 44 penetrates the insulating layer 35 over the entire circumference and electrically connects the gate electrode 16 and the inner region 21A. Therefore, the entire inner region 21A may be electrically connected to the gate electrode 16.

The second wiring layer 44 includes a second main body portion 45 and a second connection portion 46. The second main body portion 45 is embedded in the first insulating layer 36 at a position overlapping with the inner region 21A, and is electrically connected to the inner region 21A. The second connection portion 46 is provided within the second insulating layer 37 so as to overlap with the second main body portion 45 and is configured to electrically connect the second main body portion 45 and the gate electrode 16. The second main body portion 45 may be formed simultaneously with the first main body portion 42. The second connection portion 46 may be formed simultaneously with the first connection portion 43. Therefore, it is possible to suppress an increase in the number of steps involved in manufacturing the semiconductor device 10.

The plurality of diodes 25 are connected in series between the gate electrode 16 and the source electrode 13. Therefore, the number of the plurality of diodes 25, i.e., the number of the plurality of second semiconductor layers 22, may set a clamp voltage between the source electrode 13 and the gate electrode 16.

The insulating layer 35 includes a first insulating layer 36 that covers the first semiconductor layer 21, and a second insulating layer 37 that covers the first insulating layer 36. The first main body portion 42 is provided within the first insulating layer 36. The first connection portion 43 is provided within the second insulating layer 37. Therefore, the first main body portion 42 and the first connection portion 43 may be easily formed. Similarly, the second main body portion 45 is provided within the first insulating layer 36. The second connection portion 46 is provided within the second insulating layer 37. Therefore, it is possible to easily form the second main body portion 45 and the second connection portion 46.

The first connection portion 43 is not formed in a portion corresponding to the gap between the gate electrode 16 and the source electrode 13. According to this configuration, it is possible to suppress the first connection portion 43 from coming into contact with the gate electrode 16. Therefore, it is possible to suppress short-circuiting between the gate electrode 16 and the source electrode 13.

The end of the first connection portion 43 is arranged on the inner side of the first overlapping region 21B1 than the end of the first overlapping region 21B1. According to this configuration, it is possible to suppress the first connection portion 43 from coming into contact with the gate electrode 16. Therefore, it is possible to suppress short-circuiting between the gate electrode 16 and the source electrode 13.

The second semiconductor layer 22 includes four straight portions 222 and four arc-shaped corner portions 223 respectively provided between two adjacent straight portions 222. According to this configuration, a length of the second semiconductor layer 22 may be made longer than a length in the circumferential direction of the second semiconductor layer 22, which has, for example, a circular shape in a plan view. As a result, the length of the diode 25 formed by the second semiconductor layer 22 and the first semiconductor layer 21 may be increased. Therefore, it is possible to improve the ESD resistance of the semiconductor device 10.

As described above, according to the present embodiment, the following effects may be obtained.

(1) The semiconductor device 10 of the present embodiment includes the first semiconductor layer 21, the second semiconductor layer 22, the insulating layer 35, the source electrode 13, the gate electrode 16, the first wiring layer 41, and the second wiring layer 44. The second semiconductor layer 22 is formed in the first semiconductor layer 21 to have an annular shape in a plan view. The insulating layer 35 is formed on the first semiconductor layer 21. The source electrode 13 and the gate electrode 16 are formed on the insulating layer 35 and are spaced apart from each other. The second wiring layer 44 is provided within the insulating layer 35 and is configured to electrically connect the inner region 21A of the first semiconductor layer 21 surrounded by the second semiconductor layer 22 and the gate electrode 16. The first wiring layer 41 is provided within the insulating layer 35 and configured to electrically connect the outer region 21B of the first semiconductor layer 21 on the opposite side from the inner region 21A with respect to the second semiconductor layer 22 and the source electrode 13. The gate electrode 16 overlaps with the entire inner region in the plan view. The second wiring layer 44 is provided within the insulating layer 35 at a position overlapping with the inner region 21A to have an annular shape in the plan view.

The outer region 21B includes the first overlapping region 21B1 that overlaps with the source electrode 13 in the plan view, and the second overlapping region 21B2 that overlaps with the gate electrode 16 in the plan view. The first wiring layer 41 includes the first main body portion 42 and the first connection portion 43. The first main body portion 42 is embedded in the insulating layer 35 at a position overlapping with the outer region 21B, is formed in an annular shape to surround the second semiconductor layer 22, and is electrically connected to the outer region 21B. The first connection portion 43 is selectively provided within the insulating layer 35 at a position overlapping with the first overlapping region 21B1 and is configured to electrically connect the first main body portion 42 and the source electrode 13. In the plan view, the annular diode 25 formed by the first semiconductor layer 21 and the second semiconductor layer 22 is surrounded by the annularly formed first main body portion 42 and the second wiring layer 44. The annular diode 25 is electrically connected between the gate electrode 16 and the source electrode 13. This diode 25 functions as a protection diode (protection element) against electrostatic discharge and surge voltage caused by an externally connected inductor.

The semiconductor device 10 of the present embodiment includes the first main body portion 42 electrically connected to the source electrode 13 via the first connection portion 43. The first main body portion 42 is formed in an annular shape to surround the second semiconductor layer 22 and is electrically connected to the first semiconductor layer 21. Therefore, in the semiconductor device 10 of the present embodiment, the entire circumference of the annularly formed second semiconductor layer 22 contributes to the operation of the diode 25. In the semiconductor device 10 of the present embodiment, the length of the annular second semiconductor layer 22 may be made equal to the length of the diode 25 (diode length). The length of the annular first main body portion 42 electrically connected to the outer region 21B of the first semiconductor layer 21 may be set as a contact length. Accordingly, in the semiconductor device 10 of the present embodiment, it is possible to increase the diode length and the contact length, thereby improving the ESD resistance.

(2) The second wiring layer 44 penetrates the insulating layer 35 over the entire circumference to electrically connect the gate electrode 16 and the inner region 21A. Accordingly, the entire inner region 21A may be electrically connected to the gate electrode 16.

(3) The second wiring layer 44 includes the second main body portion 45 and the second connection portion 46. The second main body portion 45 is embedded in the first insulating layer 36 at a position overlapping with the inner region 21A, and is electrically connected to the inner region 21A. The second connection portion 46 is provided within the second insulating layer 37 so as to overlap with the second main body portion 45 and is configured to electrically connect the second main body portion 45 and the gate electrode 16. The second main body portion 45 may be formed simultaneously with the first main body portion 42. The second connection portion 46 may be formed simultaneously with the first connection portion 43. Accordingly, it is possible to suppress an increase in the number of steps involved in manufacturing the semiconductor device 10.

(4) The plurality of diodes 25 are connected in series between the gate electrode 16 and the source electrode 13. Accordingly, the number of the plurality of diodes 25, i.e., the number of the plurality of second semiconductor layers 22, may set the clamp voltage between the source electrode 13 and the gate electrode 16.

(5) The insulating layer 35 includes the first insulating layer 36 that covers the first semiconductor layer 21, and the second insulating layer 37 that covers the first insulating layer 36. The first main body portion 42 is provided within the first insulating layer 36. The first connection portion 43 is provided within the second insulating layer 37. Therefore, the first main body portion 42 and the first connection portion 43 may be easily formed. Similarly, the second main body portion 45 is provided within the first insulating layer 36. The second connection portion 46 is provided within the second insulating layer 37. Accordingly, it is possible to easily form the second main body portion 45 and the second connection portion 46.

(6) The first connection portion 43 is not formed in a portion corresponding to the gap between the gate electrode 16 and the source electrode 13. According to this configuration, it is possible to suppress the first connection portion 43 from coming into contact with the gate electrode 16. Accordingly, it is possible to suppress short-circuiting between the gate electrode 16 and the source electrode 13.

(7) The end portion of the first connection portion 43 is arranged on the inner side of the first overlapping region 21B1 than the end portion of the first overlapping region 21B1. According to this configuration, it is possible to suppress the first connection portion 43 from coming into contact with the gate electrode 16. Accordingly, it is possible to suppress short-circuiting between the gate electrode 16 and the source electrode 13.

(8) The second semiconductor layer 22 includes four straight portions 222 and four arc-shaped corner portions 223 respectively provided between two adjacent straight portions 222. According to this configuration, the length of the second semiconductor layer 22 may be made longer than the length in the circumferential direction of the second semiconductor layer 22, which has, for example, a circular shape in the plan view. As a result, it is possible to increase the length of the diode 25 formed by the second semiconductor layer 22 and the first semiconductor layer 21, thereby improving the ESD resistance of the semiconductor device 10.

### (Modification)

The above-described embodiment may be modified as follows, for example. The above-described embodiment and the respective modifications to be described below may be combined with each other as long as no technical contradiction occurs. In addition, in the following modifications, components in common with the above-described embodiment are designated by the same reference numerals as in the above-described embodiment, and the description thereof will be omitted.

In the above-described embodiment, a shape of the second semiconductor layer 22 may be arbitrarily changed. For example, the shape of the second semiconductor layer 22 may be a circle, an ellipse, a straight line, an L-shape, a U-shape, or the like.

In the above-described embodiment, the first connection portion 43 may be provided only in the straight portion 222B of the second semiconductor layer 22.

A shape and an arrangement position of the gate electrode 16 may be changed arbitrarily. For example, the position of the gate electrode 16 may be changed arbitrarily.

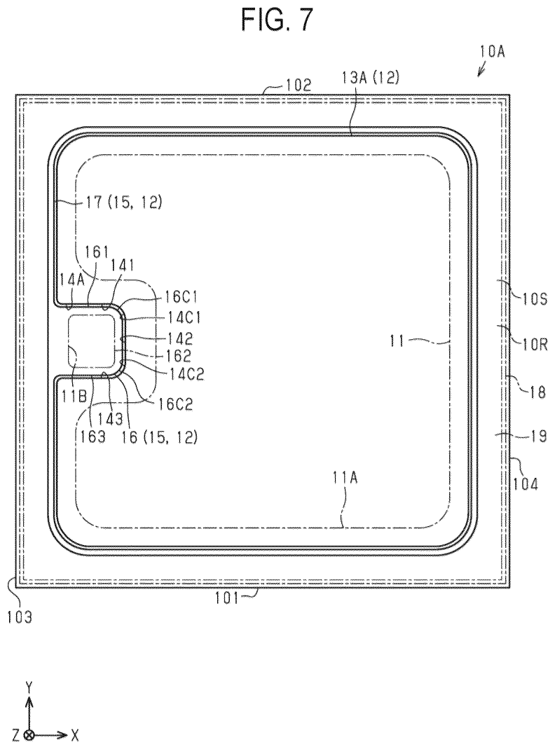

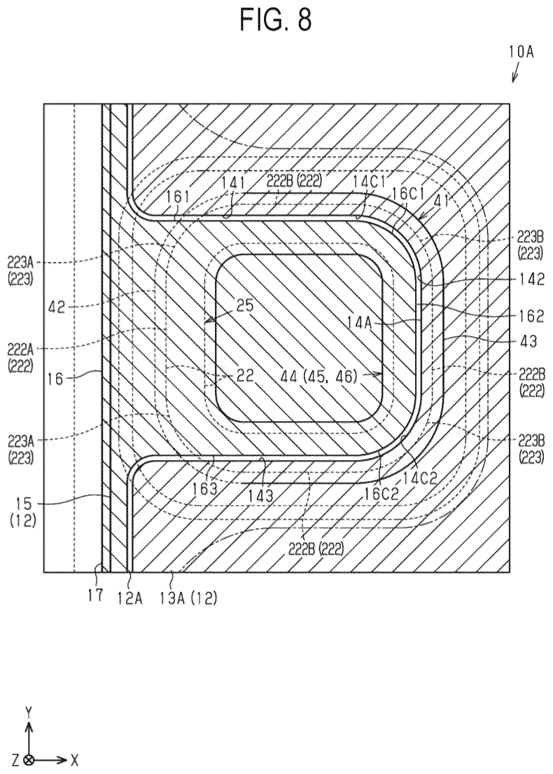

FIG. 7 is a schematic plan view of a semiconductor device 10A according to a modification. FIG. 8 is an enlarged schematic plan view showing a region including the gate electrode 16 shown in FIG. 7. In FIG. 7, the passivation layer 11 is indicated by a one-dot chain line, and the metal layer 12 is indicated by a solid line.

The metal layer 12 of the semiconductor device 10A shown in FIG. 7 may include a first metal layer 13A (source electrode 13A) and a second metal layer 15. The second metal layer 15 may include a gate electrode 16 and a gate finger 17.

The source electrode 13A may include a recess 14A by having a substantially rectangular cutout in a plan view. The recess 14A may be formed at the end of the source electrode 13A close to any of the four side surfaces 101, 102, 103, and 104 of the semiconductor device 10A. In the example of FIG. 7, the recess 14A may be provided at the end of the source electrode 13A close to the third side surface 103 of the semiconductor device 10A, and may be provided at the center in the Y direction.

The source electrode 13A includes a first side 141, a second side 142, and a third side 143 that form the recess 14A, a first curved portion 14C1 between the first side 141 and the second side 142, and a second curved portion 14C2 between the second side 142 and the third side 143. The first side 141 and the third side 143 are orthogonal to the second side 142 in a plan view. The first curved portion 14C1 and the second curved portion 14C2 are formed in an arc shape recessed toward the inside of the source electrode 13A.

As shown in FIG. 8, the first semiconductor layer 21 includes an inner region 21A surrounded by the second semiconductor layer 22, and an outer region 21B on the opposite side from the inner region 21A with respect to the second semiconductor layer 22. The outer region 21B overlaps with the first side 141, the second side 142, the third side 143, the first curved portion 14C1, and the second curved portion 14C2 of the recess 14A of the source electrode 13A. The outer region 21B includes a first overlapping region 21B1 overlapping with the source electrode 13A and a second overlapping region 21B2 overlapping with the gate electrode 16 in a plan view. The second overlapping region 21B2 are provided only on the side of the third side surface 103 of the semiconductor device 10A.

The first wiring layer 41 electrically connects the outer region 21B and the source electrode 13A. The first wiring layer 41 includes a first main body portion 42 and a first connection portion 43. As in the above-described embodiment, the first main body portion 42 is formed in an annular shape to surround the second semiconductor layer 22. The first connection portion 43 is selectively provided at a position overlapping with the first overlapping region 21B1. The first connection portion 43 electrically connects the first main body portion 42 and the source electrode 13A. The first connection portion 43 is provided along the three straight portions 222 and the corner portions 223 of the second semiconductor layer 22. The first connection portions 43 may be provided along only the three straight portions 222 of the second semiconductor layer 22.

The gate electrode 16 includes three sides 161, 162, and 163 adjacent to the source electrode 13A (recess 14A). Further, the gate electrode 16 includes corner portions 16C1 and 16C2 between two adjacent sides 161, 162, 162, and 163. In the first connection portion 43, it may be said that the gate electrode 16 is provided along the three sides 161, 162, and 163 and the corner portions 16C1 and 16C2. The first connection portion 43 may be provided only along the three sides 161, 162, and 163 of the gate electrode 16.

As in the semiconductor device 10 of the above-described embodiment, the semiconductor device 10A of this modification includes a first main body portion 42 electrically connected to the source electrode 13A via a first connection portion 43. The first main body portion 42 is formed in an annular shape to surround the second semiconductor layer 22 and is electrically connected to the first semiconductor layer 21. Therefore, in this semiconductor device 10A, the entire circumference of the annularly formed second semiconductor layer 22 contributes to the operation of the diode 25, as in the semiconductor device 10 of the above-described embodiment. Accordingly, in this semiconductor device 10A, the diode length and the contact length may be made longer than those in the semiconductor device 10 of the above-described embodiment, which makes it possible to improve the ESD resistance.

In the above-described embodiment, the cell structure of the cell region 60 may be changed arbitrarily. In an example, the semiconductor device may be configured as a semiconductor switching device including a D-MOSFET (Double Diffused MOSFET). Further, the semiconductor device may be configured as a semiconductor switching device including an IGBT (Insulated Gate Bipolar Transistor).

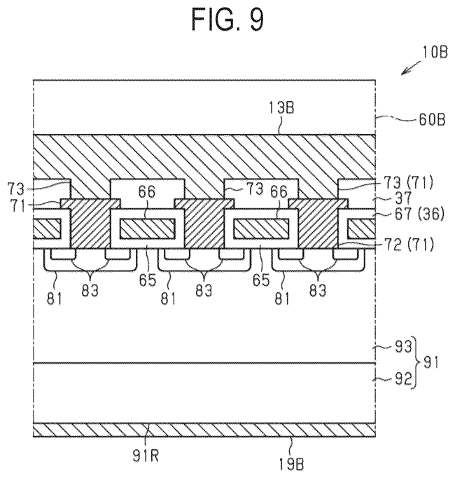

FIG. 9 shows a cross-sectional structure of a cell region 60B of a semiconductor device 10B according to a modification. This semiconductor device 10B is configured as an IGBT. The semiconductor layer 91 includes a p⁺-type collector layer 92, and an n⁻-type drift layer 93 on the collector layer 92. A channel diffusion layer 81 is formed in the drift layer 93. An emitter region 83 is formed in the channel diffusion layer 81. A gate insulating film 65 and a gate electrode 66 are formed on the semiconductor layer 91 between two adjacent channel diffusion layers 81. The channel diffusion layer 81 is of the second conductivity type (p type), and the emitter region 83 is of the first conductivity type (n⁺ type).

The gate electrode 66 is covered with an interlayer insulating film 67. An insulating layer 35 (first insulating layer 36 and second insulating layer 37) is formed on the interlayer insulating film 67. A first metal layer 13B is formed on the insulating layer 35. A third metal layer 19B is formed on the lower surface 91R of the semiconductor layer 91. In this semiconductor device 10B, the first metal layer 13B includes an emitter electrode, and the third metal layer 19B is a collector electrode.

Also in the semiconductor device 10B of this modification, as in the semiconductor device 10 of the above-described embodiment, the diode 25 constituted by the first semiconductor layer 21 and the second semiconductor layer 22 is connected between the first metal layer (emitter electrode) 13B and the gate electrode 16 of the second metal layer 15. Accordingly, in the semiconductor device 10B of this modification as well, as in the semiconductor device 10 of the above-described embodiment, it is possible to improve the ESD resistance.

As used in the present disclosure, the term “on” includes both “on” and “above” unless the context clearly indicates otherwise. Accordingly, although the phrase “a first layer may be formed on a second layer” refers to a case where the first layer is directly disposed on the second layer in contact with the second layer in one embodiment, the first layer may be disposed above the second layer without being in contact with the second layer in another embodiment. That is, the term “on” does not exclude a structure in which another layer is formed between the first layer and the second layer.

As used in the present disclosure, the Z-axis direction does not necessarily have to be a vertical direction, nor does it need to completely coincide with the vertical direction. Accordingly, in various structures according to the present disclosure (e.g., the structures shown in FIG. 1), “upper” and “lower” in the Z-axis direction described herein are not limited to “upper” and “lower” in the vertical direction. For example, the X-axis direction may be the vertical direction, or the Y-axis direction may be the vertical direction.

In the present disclosure, “a state where a member A is connected to a member B” includes a case where the member A and the member B are physically directly connected, and a case where the member A and the member B are indirectly connected via any other member that does not affect an electrical connection.

Similarly, “a state where a member C is installed between a member A and a member B” includes a case where the member A and the member C or the member B and the member C are directly connected and a case where the member A and the member C or the member B and the member C are indirectly connected via any other member that does not affect an electrical connection.

As used in the present disclosure, the expression “at least one” means “one or more” of desired options. As an example, the expression “at least one” as used herein means “only one option” or “both of two options” in a case where the number of options is two. As another example, the expression “at least one” as used herein means “only one option” or “any combination of two or more options” in a case where the number of options is three or more.

### (Supplementary Note)

The technical features that may be understood from the present disclosure are described below. Not for the purpose of limitation but for the purpose of aiding understanding, the components described in the supplementary notes are given reference numerals of the corresponding components of the above-described embodiment. Reference numerals are added by way of example to aid understanding, and the components described in each supplementary note should not be limited to the components indicated by the reference numerals.

### (Supplementary Note 1)

A semiconductor device including:
a first semiconductor layer (21) of a first conductivity type (n);
at least one second semiconductor layer (22) of a second conductivity type (p) formed in the first semiconductor layer (21) to have an annular shape in a plan view;
an insulating layer (35) formed on the first semiconductor layer (21);
a first metal layer (13) and a second metal layer (15) formed on the insulating layer (35) and spaced apart from each other;
a second wiring layer (44) provided in the insulating layer (35) and configured to electrically connect an inner region (21A) of the first semiconductor layer (21) surrounded by the at least one second semiconductor layer (22) and the second metal layer (15); and
a first wiring layer (41) provided in the insulating layer (35) and configured to electrically connect an outer region (21B) of the first semiconductor layer (21) on the opposite side from the inner region (21A) with respect to the at least one second semiconductor layer (22) and the first metal layer (13),
wherein the second metal layer (15) overlaps with an entire inner region (21A) in the plan view,
wherein the second wiring layer (44) is provided in the insulating layer (35) at a position overlapping with the inner region (21A) to have an annular shape in the plan view,
wherein the outer region (21B) includes: a first overlapping region (21B1) overlapping with the first metal layer (13) in the plan view; and a second overlapping region (21B2) overlapping with the second metal layer (15) in the plan view,
wherein the first wiring layer (41) includes: a first main body portion (42) embedded in the insulating layer (35) at a position overlapping with the outer region (21B), formed in an annular shape to surround the at least one second semiconductor layer (22), and electrically connected to the outer region (21B); and a first connection portion (43) selectively provided in the insulating layer (35) at a position overlapping with the first overlapping region (21B1) and configured to electrically connect the first main body portion (42) and the first metal layer (13), and
wherein an annular diode constituted by the first semiconductor layer (21) and the at least one second semiconductor layer (22) is surrounded by the first main body portion (42) and the second wiring layer (44), which are formed in the annular shape, in the plan view.

### (Supplementary Note 2)

The semiconductor device of Supplementary Note 1, wherein the second wiring layer (44) penetrates the insulating layer (35) over an entire circumference thereof and electrically connects the second metal layer (15) and the inner region (21A).

### (Supplementary Note 3)

The semiconductor device of Supplementary Note 1 or 2, wherein the second wiring layer (44) includes: a second main body portion (45) embedded in the insulating layer (35) at a position overlapping with the inner region (21A) and electrically connected to the inner region (21A); and a second connection portion (46) provided in the insulating layer (35) so as to overlap with the second main body portion (45) and configured to electrically connect the second main body portion (45) and the second metal layer (15).

### (Supplementary Note 4)

The semiconductor device of any one of Supplementary Notes 1 to 3, wherein the at least one second semiconductor layer (22) includes a plurality of the second semiconductor layers (22).

### (Supplementary Note 5)

The semiconductor device of any one of Supplementary Notes 1 to 4, wherein the insulating layer (35) includes a first insulating layer (36) configured to cover the first semiconductor layer (21), and a second insulating layer (37) configured to cover the first insulating layer (36).

### (Supplementary Note 6)

The semiconductor device of Supplementary Note 5, wherein the first main body portion (42) is provided in the first insulating layer (36), and the first connection portion (43) is provided in the second insulating layer (37).

### (Supplementary Note 7)

The semiconductor device of any one of Supplementary Notes 1 to 6, wherein the at least one second semiconductor layer (22) is formed in a rectangular annular shape, and
wherein the first overlapping region (21B1) overlaps with two adjacent straight portions (222B) of the at least one second semiconductor layer (22).

### (Supplementary Note 8)

The semiconductor device of Supplementary Note 7, wherein the first connection portion (43) is formed along two sides (161 and 162) adjacent to the first metal layer (13) in the plan view.

### (Supplementary Note 9)

The semiconductor device of any one of Supplementary Notes 1 to 6, wherein the at least one second semiconductor layer (22) is formed in a rectangular and annular shape, and wherein the first overlapping region (21B1) overlaps with three straight portions (222B) of the at least one second semiconductor layer (22).

### (Supplementary Note 10)

The semiconductor device of Supplementary Note 9, wherein the first connection portion (43) is formed along three sides (161, 162, and 163) adjacent to the first metal layer (13) in the plan view.

### (Supplementary Note 11)

The semiconductor device of any one of Supplementary Notes 1 to 10, wherein the first connection portion (43) is not formed in a portion corresponding to a gap (12A) between the second metal layer (15) and the first metal layer (13).

### (Supplementary Note 12)

The semiconductor device of any one of Supplementary Notes 1 to 11, wherein an end of the first connection portion (43) is arranged on the inner side of the first overlapping region (21B1) than an end of the first overlapping region (21B1).

### (Supplementary Note 13)

The semiconductor device of Supplementary Note 12, wherein the at least one second semiconductor layer (22) includes four straight portions (222) and four arc-shaped corner portions (223) respectively provided between two adjacent straight portions (222).

### (Supplementary Note 14)

The semiconductor device of Supplementary Note 13, wherein the first main body portion (42) is formed in an arc shape in conformity with the corner portions (223B) of the at least one second semiconductor layer (22).

### (Supplementary Note 15)

The semiconductor device of Supplementary Note 13 or 14, wherein the first connection portion (43) is provided only in the straight portions (222B) of the at least one second semiconductor layer (22).

### (Supplementary Note 16)

The semiconductor device of any one of Supplementary Notes 1 to 15, further including:
a semiconductor layer (31); and
an insulating layer (34) formed on the semiconductor layer (31),
wherein the first semiconductor layer (21) and the at least one second semiconductor layer (22) are formed on the insulating layer (34).

### (Supplementary Note 17)

The semiconductor device of Supplementary Note 16, wherein the semiconductor layer (31) includes a diffusion layer (63) of a first conductivity type (n) provided in a cell region (60) of the semiconductor layer (31) overlapping with the first metal layer (13) in the plan view, and
wherein the first metal layer (13) is electrically connected to the diffusion layer (63) by a first via (71) arranged at a position overlapping with the cell region (60) in the plan view.

### (Supplementary Note 18)

The semiconductor device of Supplementary Note 17, wherein the first via (71) is made of the same material as the second wiring layer (44) and the first wiring layer (41).

### (Supplementary Note 19)

The semiconductor device of any one of Supplementary Notes 16 to 18, further comprising:
a third metal layer (19) provided on the opposite side from the first metal layer (13) and the second metal layer (15) with respect to the semiconductor layer (31).

### (Supplementary Note 20)

A semiconductor device including:
a first semiconductor layer (21) of a first conductivity type (n);
at least one second semiconductor layer (22) of a second conductivity type (p) provided in the first semiconductor layer (21) and configured to divide the first semiconductor layer (21) into a first region and a second region on the opposite side of the first region;
a first insulating layer (36) formed on the first semiconductor layer (21);
a second insulating layer (37) formed on the first insulating layer (36);
a first metal layer (13) and a second metal layer (15) formed on the second insulating layer (37) and spaced apart from each other;
a first wiring layer (41) configured to electrically connect the first region and the first metal layer (13); and
a second wiring layer (44) configured to electrically connect the second region and the second metal layer (15),
wherein the second metal layer (15) overlaps with an entire second region in a plan view,
wherein the first region includes: a first overlapping region (21B1) overlapping with the first metal layer (13) in the plan view; and a second overlapping region (21B2) overlapping with the second metal layer (15) in the plan view, and
wherein the first wiring layer (41) includes: a first main body portion (42) embedded in the first insulating layer (36) at a position overlapping with the first region and electrically connected to the first region; and a first connection portion (43) selectively provided in the second insulating layer (37) at a position overlapping with the first overlapping region (21B1) and configured to electrically connect the first main body portion (42) and the first metal layer (13).

### (Supplementary Note 21)

The semiconductor device of Supplementary Note 20, wherein the second wiring layer (44) includes: a second main body portion (45) embedded in the first insulating layer (36) at a position overlapping with the second region and electrically connected to the second region; and a second connection portion (46) provided in the second insulating layer (37) so as to overlap with the second main body portion (45) and configured to electrically connect the second main body portion (45) and the second metal layer (15).

### (Supplementary Note 22)

The semiconductor device of Supplementary Note 20 or 21, wherein the at least one second semiconductor layer (22) includes a plurality of the second semiconductor layers (22).

### (Supplementary Note 23)

The semiconductor device of any one of Supplementary Notes 20 to 22, wherein the first connection portion (43) is not formed in a portion corresponding to a gap between the second metal layer (15) and the first metal layer (13).

### (Supplementary Note 24)

The semiconductor device of any one of Supplementary Notes 20 to 23, wherein an end of the first connection portion (43) is arranged on the inner side of the first overlapping region (21B1) than an end of the first overlapping region (21B1).

### (Supplementary Note 25)

The semiconductor device of any one of Supplementary Notes 20 to 24, further including:
a semiconductor layer (31); and
an insulating layer (34) formed on the semiconductor layer (31),
wherein the first semiconductor layer (21) and the at least one second semiconductor layer (22) are formed on the insulating layer (34).

### (Supplementary Note 26)

The semiconductor device of Supplementary Note 25, wherein the semiconductor layer (31) includes a diffusion layer (63) of a first conductivity type (n) provided in a cell region (60) of the semiconductor layer (31) overlapping with the first metal layer (13) in the plan view, and
wherein the first metal layer (13) is electrically connected to the diffusion layer (63) by a first via (71) arranged at a position overlapping with the cell region (60) in the plan view.

### (Supplementary Note 27)

The semiconductor device of Supplementary Note 26, wherein the first via (71) is made of the same material as the second wiring layer (44) and the first wiring layer (41).

### (Supplementary Note 28)

The semiconductor device of any one of Supplementary Notes 25 to 27, further including:
a third metal layer (19) provided on the opposite side from the first metal layer (13) and the second metal layer (15) with respect to the semiconductor layer (31).

The above description is merely exemplary. Those skilled in the art will recognize that many more combinations and substitutions are possible, in addition to the components and the methods (manufacturing process) listed for the purpose of describing the techniques of the present disclosure. The present disclosure is intended to cover all alternatives, variations, and modifications falling within the scope of the present disclosure including the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a first semiconductor layer of a first conductivity type;
at least one second semiconductor layer of a second conductivity type formed in the first semiconductor layer to have an annular shape in a plan view;
an insulating layer formed on the first semiconductor layer;
a first metal layer and a second metal layer formed on the insulating layer and spaced apart from each other;
a second wiring layer provided in the insulating layer and configured to electrically connect an inner region of the first semiconductor layer surrounded by the at least one second semiconductor layer and the second metal layer; and
a first wiring layer provided in the insulating layer and configured to electrically connect an outer region of the first semiconductor layer on the opposite side from the inner region with respect to the at least one second semiconductor layer and the first metal layer,
wherein the second metal layer overlaps with an entire inner region in the plan view,
wherein the second wiring layer is provided in the insulating layer at a position overlapping with the inner region to have an annular shape in the plan view,
wherein the outer region includes:
a first overlapping region overlapping with the first metal layer in the plan view; and
a second overlapping region overlapping with the second metal layer in the plan view,
wherein the first wiring layer includes:
a first main body portion embedded in the insulating layer at a position overlapping with the outer region, formed in an annular shape to surround the at least one second semiconductor layer, and electrically connected to the outer region; and
a first connection portion selectively provided in the insulating layer at a position overlapping with the first overlapping region and configured to electrically connect the first main body portion and the first metal layer, and
wherein an annular diode constituted by the first semiconductor layer and the at least one second semiconductor layer is surrounded by the first main body portion and the second wiring layer, which are formed in the annular shape, in the plan view.

2. The semiconductor device of claim 1, wherein the second wiring layer penetrates the insulating layer over an entire circumference thereof and electrically connects the second metal layer and the inner region.

3. The semiconductor device of claim 1, wherein the second wiring layer includes:
a second main body portion embedded in the insulating layer at a position overlapping with the inner region and electrically connected to the inner region; and
a second connection portion provided in the insulating layer so as to overlap with the second main body portion and configured to electrically connect the second main body portion and the second metal layer.

4. The semiconductor device of claim 1, wherein the at least one second semiconductor layer includes a plurality of second semiconductor layers.

5. The semiconductor device of claim 1, wherein the insulating layer includes a first insulating layer configured to cover the first semiconductor layer, and a second insulating layer configured to cover the first insulating layer.

6. The semiconductor device of claim 5, wherein the first main body portion is provided in the first insulating layer, and the first connection portion is provided in the second insulating layer.

7. The semiconductor device of claim 1, wherein the at least one second semiconductor layer is formed in a rectangular annular shape, and
wherein the first overlapping region overlaps with two adjacent straight portions of the at least one second semiconductor layer.

8. The semiconductor device of claim 7, wherein the first connection portion is formed along two sides adjacent to the first metal layer in the plan view.

9. The semiconductor device of claim 1, wherein the at least one second semiconductor layer is formed in a rectangular annular shape, and
wherein the first overlapping region overlaps with three straight portions of the at least one second semiconductor layer.

10. The semiconductor device of claim 9, wherein the first connection portion is formed along three sides adjacent to the first metal layer in the plan view.

11. The semiconductor device of claim 1, wherein the first connection portion is not formed in a portion corresponding to a gap between the second metal layer and the first metal layer.

12. The semiconductor device of claim 1, wherein an end of the first connection portion is arranged on the inner side of the first overlapping region than an end of the first overlapping region.

13. The semiconductor device of claim 12, wherein the at least one second semiconductor layer includes four straight portions and four arc-shaped corner portions respectively provided between two adjacent straight portions.

14. The semiconductor device of claim 13, wherein the first main body portion is formed in an arc shape in conformity with the corner portions of the at least one second semiconductor layer.

15. The semiconductor device of claim 13, wherein the first connection portion is provided only in the straight portions of the at least one second semiconductor layer.

16. The semiconductor device of claim 1, further comprising:
a semiconductor layer; and
an insulating layer formed on the semiconductor layer,
wherein the first semiconductor layer and the at least one second semiconductor layer are formed on the insulating layer.

17. The semiconductor device of claim 16, wherein the semiconductor layer includes a diffusion layer of the first conductivity type provided in a cell region of the semiconductor layer overlapping with the first metal layer in the plan view, and
wherein the first metal layer is electrically connected to the diffusion layer by a first via arranged at a position overlapping with the cell region in the plan view.

18. The semiconductor device of claim 17, wherein the first via is made of the same material as the second wiring layer and the first wiring layer.

19. A semiconductor device comprising:
a first semiconductor layer of a first conductivity type;
a second semiconductor layer of a second conductivity type provided in the first semiconductor layer and configured to divide the first semiconductor layer into a first region and a second region on the opposite side of the first region;
a first insulating layer formed on the first semiconductor layer;
a second insulating layer formed on the first insulating layer;
a first metal layer and a second metal layer formed on the second insulating layer and spaced apart from each other;
a first wiring layer configured to electrically connect the first region and the first metal layer; and
a second wiring layer configured to electrically connect the second region and the second metal layer,
wherein the second metal layer overlaps with an entire second region in a plan view,
wherein the first region includes:
a first overlapping region overlapping with the first metal layer in the plan view; and
a second overlapping region overlapping with the second metal layer in the plan view, and
wherein the first wiring layer includes:
a first main body portion embedded in the first insulating layer at a position overlapping with the first region; and
a first connection portion selectively provided in the second insulating layer at a position overlapping with the first overlapping region and configured to electrically connect the first main body portion and the first metal layer.
